(19) United States
(12) Patent Application Publication
(10) Pub. No.: US 2024/0005162 A1
(43) Pub. Date: Jan. 4, 2024

(54) ERROR-TRIGGERED LEARNING OF MULTI-LAYER MEMRISTIVE SPIKING NEURAL NETWORKS

(71) Applicants: University of Zurich, Zurich (CH); King Abdullah University of Science and Technology, Thuwal (SA); The Regents of the University of California, Oakland, CA (US)

(72) Inventors: Mohammed FOUDA, Irvine, CA (US); Emre NEFTCI, Irvine, CA (US); Fadi KURDAHI, Irvine, CA (US); Ahmed ELTAWIL, Irvine, CA (US); Melika PAYVAND, Zurich (CH)

(21) Appl. No.: 18/037,024

(22) PCT Filed: Nov. 19, 2021
(86) PCT No.: PCT/US2021/072501

§ 371 Date: May 15, 2023

Related U.S. Application Data
(60) Provisional application No. 63/116,271, filed on Nov. 20, 2020.

(51) Int. Cl. G06N 3/084; G06N 3/049

(52) U.S. Cl. CPC G06N 3/084; G06N 3/049

(57) ABSTRACT

The present disclosure presents neural network learning systems and methods. One such method comprises receiving an input current signal; converting the input current signal to an input voltage pulse signal utilized by a memristive neuromorphic hardware of a multi-layered spiked neural network module; transmitting the input voltage pulse signal to the memristive neuromorphic hardware of the multi-layered spiked neural network module; performing a layer-by-layer calculation and conversion on the input voltage pulse signal to complete an on-chip learning to obtain an output signal; sending the output signal to a weight update circuitry module; and/or calculating, by the weight update circuitry module, an error signal and based on a magnitude of the error signal, triggering an adjustment of a conductance value of the memristive neuromorphic hardware so as to update synaptic weight values stored by the memristive neuromorphic hardware. Other methods and systems are also provided.

### CROSS-REFERENCE TO RELATED APPLICATION

This application claims priority to co-pending U.S. provisional application entitled, “Error-Triggered Learning of Multi-Layer Memristive Spiking Neural Networks,” having Ser. No. 63/116,271, filed Nov. 20, 2020, which is entirely incorporated herein by reference.

### STATEMENT REGARDING FEDERALLY SPONSORED RESEARCH OR DEVELOPMENT

This invention was made with Government support under Grant No. 1652159, awarded by the National Science Foundation (NSF). The Government has certain rights in the invention.

### TECHNICAL FIELD

The present disclosure is generally related to neuromorphic computing systems and related methods.

### BACKGROUND

The implementation of learning dynamics as synaptic plasticity in neuromorphic hardware can lead to highly efficient, lifelong learning systems. While gradient Backpropagation (BP) is the workhorse for training nearly all deep neural network architectures, the computation of gradients involves information that is not spatially and temporally local. This non-locality is incompatible with neuromorphic hardware. Recent work addresses this problem using Surrogate Gradient (SG), local learning, and an approximate forward-mode differentiation. SGs define a differentiable surrogate network used to compute weight updates in the presence of non-differentiable spiking non-linearities. Local loss functions enable updates to be made in a spatially local fashion. The approximate forward mode differentiation is a simplified form of Real-Time Recurrent Learning (RTRL) that enables online learning using temporally local information. The result is a learning rule that is both spatially and temporally local, which takes the form of a three-factor synaptic plasticity rule. The SG approach reveals, from first principles, the mathematical nature of the three factors, enabling thereby a distributed and online learning dynamic.

### SUMMARY

Embodiments of the present disclosure provide neural network learning systems and related methods. Briefly described, one embodiment of the system, among others, includes an input circuitry module; a multi-layer spiked neural network with memristive neuromorphic hardware; and a weight update circuitry module. The input circuitry module is configured to receive an input current signal and convert the input current signal to an input voltage pulse signal utilized by the memristive neuromorphic hardware of the multi-layered spiked neural network module and is configured to transmit the input voltage pulse signal to the memristive neuromorphic hardware of the multi-layered spiked neural network module. Further, the multi-layer spiked neural network is configured to perform a layer-by-layer calculation and conversion on the input voltage pulse signal to complete an on-chip learning to obtain an output signal. Additionally, the multi-layer spiked neural network is configured to transmit the output signal to the weight update circuitry module. As such, the weight update circuitry module is configured to implement a synaptic function by using a conductance modulation characteristic of the memristive neuromorphic hardware and is configured to calculate an error signal and based on a magnitude of the error signal, trigger an adjustment of a conductance value of the memristive neuromorphic hardware so as to update synaptic weight values stored by the memristive neuromorphic hardware.

The present disclosure can also be viewed as providing neural network learning methods. One such method comprises receiving an input current signal; converting the input current signal to an input voltage pulse signal utilized by a memristive neuromorphic hardware of a multi-layered spiked neural network module; transmitting the input voltage pulse signal to the memristive neuromorphic hardware of the multi-layered spiked neural network module; performing a layer-by-layer calculation and conversion on the input voltage pulse signal to complete an on-chip learning to obtain an output signal; sending the output signal to a weight update circuitry module; and/or calculating, by the weight update circuitry module, an error signal and based on a magnitude of the error signal, triggering an adjustment of a conductance value of the memristive neuromorphic hardware so as to update synaptic weight values stored by the memristive neuromorphic hardware.

In one or more aspects of the system/method, the memristive neuromorphic hardware comprises memristive crossbar arrays; a row of a memristive crossbar array comprises a plurality of memristive devices; the error signal is generated for each row of the memristive crossbar array, wherein for an individual error signal, each of the plurality of memristive devices of a row associated with the individual error signal is updated together based on a magnitude of the individual error signal; the input circuitry module comprises pseudo resistors; the weight update circuitry module is configured to generate a signal to update the synaptic weight values or to bypass updating the synaptic weight values based on the magnitude of the error signal; the weight update circuitry module increases the synaptic weight values; the weight update circuitry module decreases the synaptic weight values; updating of synaptic weights are triggered based on a comparison of the magnitude of the error signal within an error threshold value; and/or the error threshold value is adjustable by the weight update circuitry module.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 shows an exemplary chart of error discretization used for error-triggered learning in accordance with the present disclosure.

FIG. 2 depicts the details of the learning circuits in a crossbar-like architecture in accordance with various embodiments of the present disclosure.

FIG. 3A depicts an architecture of a Three-Factor Error-Triggered Rule in accordance with various embodiments of the present disclosure.

FIG. 3B shows a table (Table I) of results demonstrating a small loss in accuracy across the two tasks when updates are error-triggered in accordance with the present disclosure.

FIG. 4 shows representations of signals used during learning of synaptic weights at the start (epoch=0), middle (epoch=2), and end of learning (epoch=15) for a fully connected network in accordance with the present disclosure.

FIG. 5 illustrates charts of task accuracy versus a number of updates relative to continuous learning in accordance with the present disclosure.

FIG. 6A illustrates an exemplary hardware architecture containing Neuromorphic Cores (NCs) and Processing Cores (PCs) in accordance with various embodiments of the present disclosure.

FIG. 6B shows a truth table (Table II) of an error-triggered ternary update rule in accordance with the present disclosure.

FIG. 7 depicts an exemplary neuromorphic learning architecture compatible with an address-event representation (AER) communication scheme in accordance with various embodiments of the present disclosure.

FIG. 8 shows circuitry for a double integration scheme using Q and P integrators in accordance with various embodiments of the present disclosure.

FIG. 9 illustrates exemplary learning circuits representing normalizing, spike generation, and box functions in accordance with various embodiments of the present disclosure.

FIG. 10 depicts simulation results for input events on two different input channels and their double integrated output P₀ and P₁ in accordance with the present disclosure.

FIGS. 11A-11B illustrates configurability on an exemplary box function in accordance with various embodiments of the present disclosure, such that FIG. 11A shows that the width of the box function can be varied and FIG. 11B depicts how the box function midpoint can be moved by changing the I_{L} value in FIG. 9.

FIG. 12 illustrates charts of learning signals along with the voltages that are dropped across the memristive devices for a 2×2 array in accordance with various embodiments of the present disclosure.

### DETAILED DESCRIPTION

The present disclosure describes various embodiments of systems, apparatuses, and methods of error-triggered learning of neural networks. Although recent breakthroughs in neuromorphic computing show that local forms of gradient descent learning are compatible with Spiking Neural Networks (SNNs) & synaptic plasticity and although SNNs can be scalably implemented using neuromorphic VLSI, an architecture that can learn using gradient-descent in situ is still missing. Accordingly, the present disclosure provides a local, gradient-based, error-triggered learning algorithm with online ternary weight updates. Such an exemplary algorithm enables online training of multi-layer SNNs with memristive neuromorphic hardware showing a small loss in the performance compared with the state-of-the-art. The present disclosure additionally provides various embodiments of a hardware architecture based on memristive crossbar arrays to perform the required vector-matrix multiplications. In various embodiments, peripheral circuitry including presynaptic, post-synaptic, and write circuits required for online training, are designed in the subthreshold regime for power saving with a standard 180 nm CMOS process.

Accordingly, in the present disclosure, a hardware architecture, learning circuit, and learning dynamics that meet the realities of circuit design and mathematical rigor are provided. The resulting learning dynamic is an error-triggered variation of gradient-based three factor rules that is suitable for efficient implementation in Resistive Crossbar Arrays (RCAs). Conventional backpropagation schemes require separate training and inference phases which is at odds with learning efficiently on a physical substrate. In an exemplary learning dynamic, there is no backpropagation through the main branch of the neural network. Consequently, the learning phase can be naturally interleaved with the inference dynamics and only elicited when a local error is detected. Furthermore, error-triggered learning leads to a smaller number of parameter updates necessary to reach the final performance, which positively impacts the endurance and energy efficiency of the training, by factor up to 88×. In various embodiments, RCAs present an efficient implementation solution for Deep Neural Networks (DNNs) acceleration, and Vector Matrix Multiplication (VMM), which is the corner-stone of DNNs, is performed in one step compared to O(N²) steps for digital realizations where N is the vector dimension. A surge of efforts focused on using RCAs for Artificial Neural Networks (ANNs) such as but comparatively few works utilize RCAs for spiking neural networks trained with gradient-based methods. Thanks to the versatility of an exemplary algorithm of the present disclosure, RCAs can be fully utilized with suitable peripheral circuits. The present disclosure shows that an exemplary learning dynamic is particularly well suited for the RCA-based design and performs near or at deep learning proficiencies with a tunable accuracy-energy trade-off during learning.

In general, learning in neuromorphic hardware can be performed as off-chip learning, or using a hardware-in-the-loop training, where a separate processor computes weight updates based on analog or digital states. While these approaches lead to performance that is on par with conventional deep neural networks, they do not address the problem of learning scalably and online. In a physical implementation of learning, the information for computing weight updates must be available at the synapse. One approach is to convey this information to the neuron and synapses. However, this approach comes at a significant cost in wiring, silicon area, and power. For an efficient implementation of on-chip learning, it is necessary to design an architecture that naturally incorporates the local information at the neuron and the synapses. For example, Hebbian learning or its spiking counterpart Spike Time Dependent Plasticity (STDP), depend on presynaptic and post-synaptic information and thus satisfy this requirement. Consequently, many existing on-chip learning approaches focus on their implementation in the forms of unsupervised and semi-supervised learning. There have also been efforts in combining CMOS and memristor technologies to design supervised local error-based learning circuits using only one network layer by exploiting the properties of memristive devices. However, these works are limited in learning static patterns or shallow networks.

In the present disclosure, the general multi-layer learning problem is targeted by taking into account neural dynamics and multiple layers. Currently, Intel Loihi research chip, Spinnaker 1 and 2, and the Brainscales-2 have the ability to implement a vast variety of learning rules. Spinnaker and Loihi are both research tools that provide a flexible programmable substrate that can implement a vast set of learning algorithms at the cost of more power and chip area consumption. For example, Loihi and Spinnakers's flexibility is enabled by three embedded x86 processor cores, and Arm cores, respectively. The plasticity processing unit used in Brainscales-2 is a general-purpose processor for computing weight updates based on neural states and extrinsic signals. Although effective for inference stages, the learning dynamics do not break free from the conventional computing methods or use high precision processors and a separate memory block. In addition to requiring large amounts of memory to implement the learning, such implementations are limited by the von-Neumann bottleneck and are power hungry due to shuttling the data between the memory and the processing units.

The present disclosure extends the theory, system architecture, and circuits to improve scalability, area, and power. As such, the present disclosure implements an error-triggered learning algorithm to make learning fully ternary to suit the targeted memristor-based RCA hardware, presents a complete and novel hardware architecture that enables asynchronous error-triggered updates according to an exemplary algorithm, and provides an implementation of the neuromorphic core, including memristive crossbar peripheral circuits, update circuitry, and pre- and post-synaptic circuits.

An exemplary local, gradient-based, error-triggered learning algorithm with online ternary weight updates enables online training of multilayer spiking neural networks with memristive neuromorphic hardware showing a negligible loss in the performance compared with the state-of-the-art. The present disclosure provides a hardware architecture based on memristive crossbar arrays to perform vector matrix-multiplications. Peripheral circuitry including presynaptic, postsynaptic, and write circuits utilized for online training are designed in the subthreshold regime for power saving with a standard 180 nm CMOS process in various embodiments. Exemplary learning algorithms offer more energy efficient training framework with more than 80× energy improvement for DVSGesture and NMINST Datasets. In addition to improving the lifetime of RRAMs with the same ratio, advantageous features include less energy consumption, longer lifetime for RRAMs, and higher versatility compared to existing architectures.

Correspondingly, an exemplary neural network model of the present disclosure contains networks of plastic integrate-and-fire neurons, in which the models are formalized in discrete-time to make the equivalence with classical artificial neural networks more explicit. However, these dynamics can also be written in continuous-time without any conceptual changes. The neuron and synapse dynamics written in vector form are:

U^{l}[t]=W^{l}P^{l}[t]−δR^{l}[t], S^{l}[t]=Θ(U^{l}[t])

P^{l}[t+1]−α^{l}P[t]+Q^{l}[t],

Q^{l}[t+1]=β^{l}Q[t]+S^{l-1}[t],

R^{l}[t+1]=γᵢR^{l}[t]+S^{l}[t]. (1)

where U^{l}[t]∈ [symbol] , l∈[1, L] is the membrane potential of N^{l} neurons at layer l at time step t, W^{l} is the synaptic weight matrix between layer l−1 and l, and S^{l} is the binary output of this neuron. Θ is the step function acting as a spiking activation function, i.e. (Θ(x)=1 if x≥0, and Θ(x)=0 otherwise). The terms α^{l}, γ^{l}, β^{l}∈ [symbol] capture the decay dynamics of the membrane potential, the synapse and the refractory (resetting) state R^{l}, respectively. States P^{l} describe the post-synaptic potential in response to input events S^{l-1}. States Q^{l} can be interpreted as the synaptic conductance state. The decay terms are written in vector form, meaning that every neuron is allowed to have a different leak. It is important to take variations of the leak across neurons into account because fabrication mismatch in subthreshold implementations may lead to substantial variability in these parameters. R is a refractory state that resets and inhibits the neuron after the neuron has emitted a spike, and δ∈ [symbol] is the constant that controls its magnitude. Note that Equation (1) is equivalent to a discrete-time version of a type of Leaky Integrate & Fire (LI&F) and the Spike Response Model (SRM) with linear filters. The same dynamics can be written for recurrent spiking neural networks, whereby the same layer feeds into itself, by adding another connectivity matrix to each layer to account for the additional connections. This SNN and the ensuing learning dynamics can be transformed into a standard binary neural network by setting all decay terms and δ to 0, which is equivalent to replacing P with S and dropping R and Q.

Assuming a global cost function [symbol] [t] defined for the time step t, the gradients with respect to the weights in layer l are formulated as three factors:

$${∇}_{{W}^{ι}} ℒ [ t ] = \frac{\partial ℒ}{\partial {S}^{l}} \frac{\partial {S}^{l}}{\partial {U}^{l}} \frac{{dU}^{l}}{{dW}^{l}} \qquad ( 2 )$$

where

$$\frac{d}{{dW}^{l}}$$

is used to indicate a total derivative, because the differentiated state may indirectly depend on the differentiated parameter W, and dropped the notation of the time [t] for clarity.

The rightmost factor of Equation (2) (above) describes the change of the membrane potential as a function of weight W^{l}. This term can be computed as

$${P}^{l} [ t ] - δ \frac{{dR}^{l} [ t ]}{{dW}^{l}}$$

for the neuron defined by Equation (1). Note that, as in all neural network calculus, this term is a sparse, rank-3 tensor. However, for clarity and the ensuing simplifications, the term is written here as a vector. The term with R involves a dependence of the past spiking activity of the neuron, which significantly increases the complexity of the learning dynamics. Fortunately, this dependence can be ignored during learning without empirical loss in performance.

The middle factor of Equation (2) is the change in spiking state as a function of the membrane potential, i.e. the derivative of Θ. Θ is non-differentiable but can be replaced by a surrogate function such as a smooth sigmoidal or piecewise constant function. Experiments make use of a piecewise linear function, such that this middle factor becomes the box function:

$$\frac{\partial {S}^{l}}{\partial {U}^{l}} := B ( {U}_{i}^{l} ) = 1$$

if u₋<Uᵢ^{l}<u₊ and 0 otherwise. B^{l} is defined then as the diagonal matrix with elements B(Uᵢ^{l}) on the diagonal.

The leftmost factor of Equation (2) describes how the change in the spiking state affects the loss. It is commonly called the local error (or the “delta”) and is typically computed using gradient Backpropagation (BP). It is assumed for the moment that these local errors are available and denoted as err^{l}. Using standard gradient descent, the weight updates become:

ΔW^{l}=−η∇w^{l} [symbol] =−η(err^{l}B^{l})^{T}P^{l}, *3)

In scalar form, the rule simplifies as follows:

ΔWᵢⱼ^{l}=−ηerrᵢ^{l}Pⱼ^{l}, if u₋<Uᵢ< [symbol] ₊, (4)

where η is the learning rate.

By virtue of the chain rule of calculus, Equation (2) reveals that the derivative of the loss function in a neural network (the first term or the equation

$$\frac{\partial ℒ}{\partial {S}^{l}} )$$

depends solely on the output state S, in which the output state S is a binary vector with N^{l} and can naturally be communicated across a chip using event-based communication techniques with minimal overhead. The computed errors

$$( \frac{\partial ℒ}{\partial {S}^{l}} )$$

are vectors of the same dimension, but are generally reals, i.e. defined in [symbol] . For in situ learning, the error vector must be available at the neuron. To make this communication efficient, a tunable threshold on the errors is introduced and errors are encoded using positive and negative events as follows:

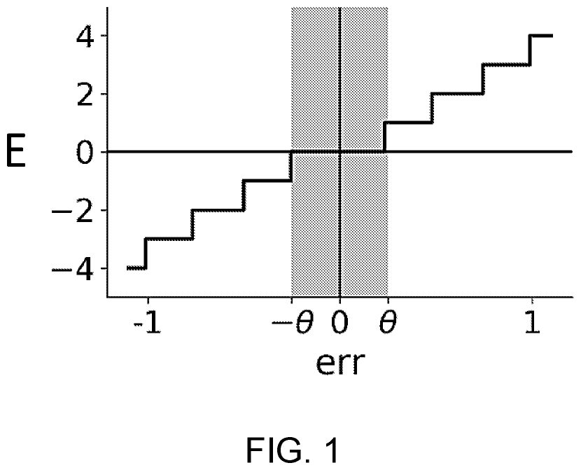

E^{l}=sign(err^{l})(|err^{l}|÷θ^{l}), (5)

where θ^{l}∈ [symbol] is a constant or slowly varying error threshold unique to each layer l and ÷ is an integer division. FIG. 1 illustrates the error discretization used for error-triggered learning. E here is the error magnitude as a function of the real valued error err. Note that although the magnitude of E can be larger than 1, these events are (1) rare after a few learning iterations and (2) represented as multiple ternary events. Note that in the formulation above, Eᵢ can exceed −1 and 1. In this case, multiple updates are made. Using this encoding, the parameter update rule written in scalar form becomes:

ΔWᵢⱼ^{l}=−\tilde{η}Eᵢ^{l}B(Uᵢ^{l})Pⱼ^{l}, (6)

where \tilde{η}=ηθ is the new learning rate that subsumes the value of θ. Thus, an update takes place on an error of magnitude θ and if B(Uᵢ^{l})=1. The sign of the weight update is −Eᵢ^{l} and its magnitude \tilde{η}Pᵢ^{l}. Provided that the layer-wide update magnitude can be modulated proportionally to \tilde{η}, this learning rule implies two comparisons and an addition (subtraction).

When implementing the rule in memristor crossbar arrays, using analog values for P would require coding its value as a number of pulses, which would require extra hardware. In order to avoid sampling the P signal and simplify the implementation, P value can be further discretized to a binary signal by thresholding (using a simple comparator):

$$\frac{d {\tilde{U}}^{l}}{{dW}^{l}} = c \tilde{P} , with \tilde{P} = Θ ( P - \overline{p} )$$

where c and \tilde{p} are constants, and \tilde{P} is the binarized P. This comparator is only activated upon weight updates and the analog value is otherwise used in the forward path. Since \tilde{P}∈{0,1}, the constant c can be subsumed in the learning rate i and the parameter update becomes ternary ΔWᵢⱼ^{l}∈{−\tilde{η},0,\tilde{η}}.

In various embodiments, an exemplary circuit implementation of the spiking neural network differs from classical ones. Generally, the rows of crossbar arrays are driven by (spikes) and integration takes place at each column. While this is beneficial in reducing read power, it renders learning more difficult because the variables necessary for learning in SNNs are not local to the crossbar. Instead, the crossbar is used as a vector-matrix multiplication of pre-synaptic trace vectors P^{l} and synaptic weight matrices W^{l}. Using this strategy, a single trace Pᵢ^{l} per neuron supports both inference and learning. Furthermore, this property means that learning is immune to the mismatch in P^{l}, and can even exploit this variation for reducing the loss.

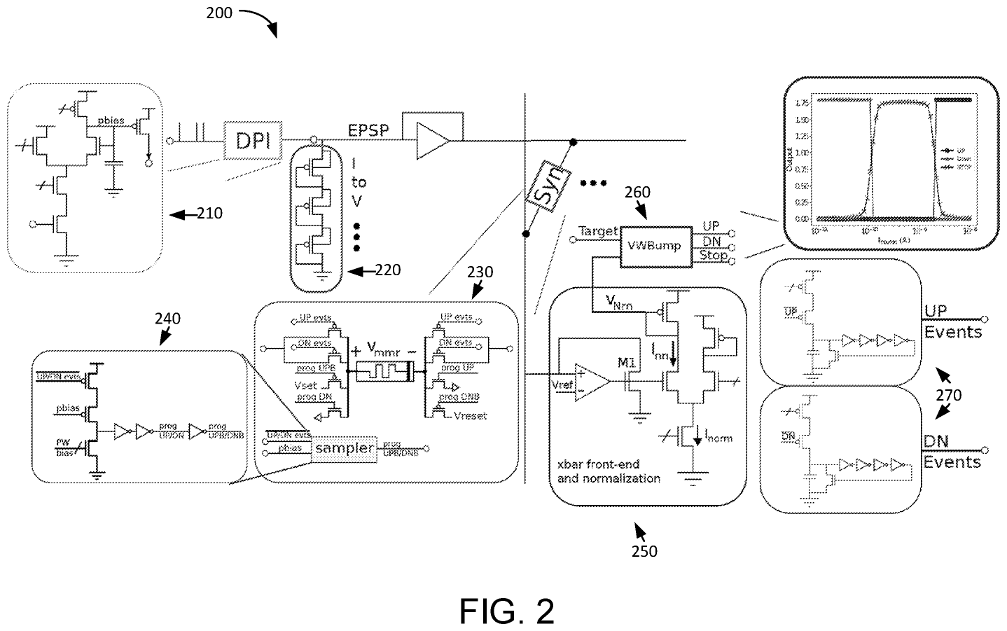

FIG. 2 depicts the details of the learning circuits 200 in a crossbar-like architecture which is compatible with the address-event representation (AER) as the conventional scheme for communication between neuronal cores in many neuromorphic chips. Components include a Differential-Pair Integrator (DPI) circuit 210 generating P in the current form; pseudo resistors 220 converting input current into a voltage driving the crossbar array; synapse 230 with the controlling switches; sampling circuitry 240 generating pulses to program the memristive devices; crossbar front-end 250 and normalization of the crossbar current; bump circuitry 260 comparing the crossbar current to a target and generating the direction of the error; and a bidirectional neuron 270 producing up and down events.

In this circuit, only P is shown and ∝_{Q}=0. This type of architecture includes multi-T/1R. The traces P are generated through a Differential-Pair Integrator (DPI) circuit 210 which generates a tunable exponential response at each input event in the form of a sub-threshold current. The current is linearly converted to voltage using pseudo resistors 220 in the I-to-V block in FIG. 2. The exponentially decaying voltage is buffered and drives the entire crossbar row in accordance with Equation (1).

For every neuron, different voltages (corresponding to Pⱼ) are applied to the top electrode of the corresponding memristive device whose bottom electrode is pinned by the crossbar front-end 250 (FIG. 2). This block pins the entire column to a reference voltage (V_{ref}) and reads out the sum of the currents generated by the application of Ps across the memristors in the column. As a result, a voltage is developed on the gate of the M1 connected to a differential pair which re-normalizes the sum of the currents from the crossbar to Iₙₒᵣₘ. This ensures that the currents remain in the subthreshold regime for the next stage of the computation which is the ternary error generation as is specified in Equation (5). This is done through the Variable Width Bump (VWBump) circuit that compares Iₙₙ to the target ŷ, with a stop region. Thus, the VWBump circuit output indicates the sign of the weight update (up or down) or stop-learning (no update). The circuit (not shown) is based on the bump circuit, which contains a differential pair for the comparison and a current correlator for the stop region, and is modified to have a tunable stop-learning region. The boundaries of this region play the role of θ in Equation (5). The output of the block is plotted in the inset of FIG. 2, which shows the Up, Down, and STOP outputs.

The Up and Down signals trigger the oscillators 270 which generate the bipolar Eᵢ events. According to Equation (6), the magnitude of the weight update is Pⱼ, and thus Pⱼ is sampled at the onset of Eᵢ. To do so, the exponential current is regenerated in the entire row by propagating p_{bias} shown in the DPI circuit block 210 and sample it by the up and down events. This is done through the sampling circuit 240 which contains two PMOS transistors in series connected to the up/down events and p_{bias} respectively. The NMOS transistor is biased to generate a current much smaller than that of the DPI and as a result, the higher the DPI current, the higher the input of the following inverter during the event pulse, and thus it takes longer for the NMOS to discharge that node. This results in a pulse width varying linearly with Pⱼ, in agreement with Equation (6). The linear pulse width can be approximated with multiple pulses which results in a linear conductance update in memristive devices.

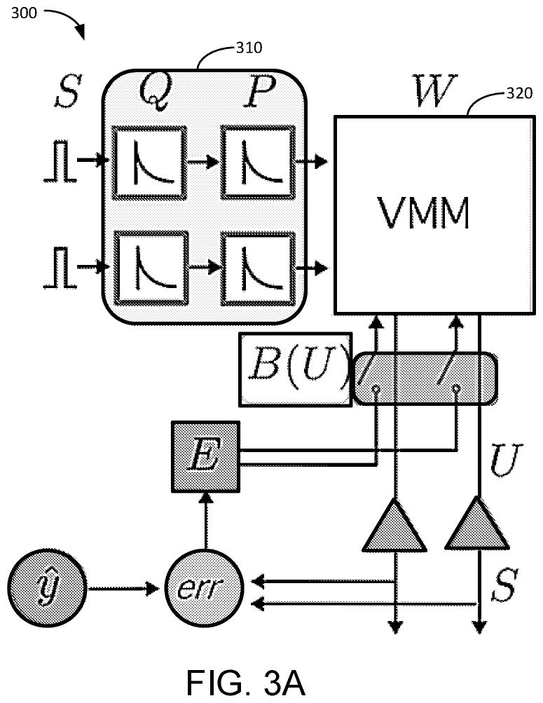

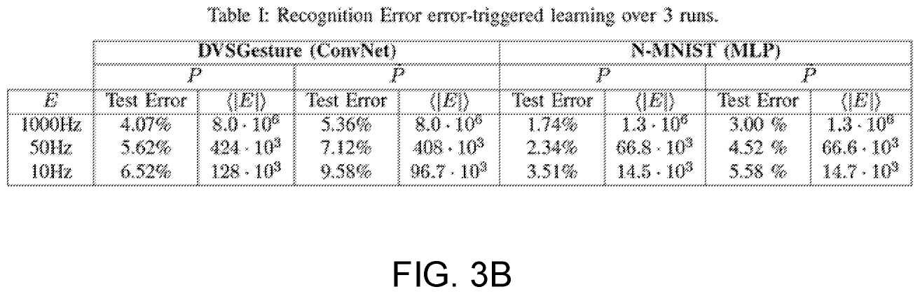

As discussed earlier, the factorization of the learning rule in three terms enables a natural distribution of the learning dynamics. The factor Eᵢ^{l} can be computed extrinsically, outside of the crossbar, and communicated via binary events (respectively corresponding to E=−1 or E=1) to the neurons. A high-level architecture 300 of the design is shown in FIG. 3A. In particular, the figure depicts an architecture 300 of a Three-Factor Error-Triggered Rule in accordance with various embodiments of the present disclosure. As shown, input spikes S are integrated through P in an input circuitry block or module 310; vector P is multiplied with W resulting in U in an array of memristor devices; output spikes S are then compared with local targets 9; and bipolar error events E are fed back to each neuron within a weight update circuitry block or module 320. Updates are made if u₋<U<u₊. R is omitted in this diagram to reduce clutter.

The computations of E can be performed as part of another spiking neural network or on a general-purpose processor. The present disclosure is agnostic to the implementation of this computation, provided that the error Eᵢ^{l} is projected back to neuron i in one time step and that it can be calculated using S^{l}.

If l<L (meaning it is not the output layer), then computing Eᵢ^{l} requires solving a deep credit assignment problem. Gradient BP can solve this, but is not compatible with a physical implementation of the neural network, and is extremely memory intensive in the presence of temporal dynamics. Several approximations have emerged recently to solve this, such as feedback alignment, and local losses defined for each layer. For classification, examples of local losses are layer-wise classifiers (using output labels) and supervised clustering, which can perform on par with BP in classical ML benchmark tasks. Various embodiments of the present disclosure use a layer-wise local classifier using a mean-squared error loss defined as [symbol] =∥Σₖ₌₁^{C}(Jᵢₖ^{l}Sₖ^{l}−Ŷₖ)∥₂, where Jᵢₖ^{l} is a random, fixed matrix, Ŷₖ are one-hot encoded labels, and C is the number of classes. The gradients of [symbol] involve backpropagation within the time step t and thus requires the symmetric transpose, J^{l,T}. If this symmetric transpose is available, then can be optimized directly. To account for the case where J^{T} is unavailable, for example in mixed signal systems, training is through feedback alignment using another random matrix H I whose elements are equal to Hᵢⱼ^{l}=Jᵢⱼ^{l}ωᵢⱼ^{l} with Gaussian distributed

$${ω}_{ij}^{l} ∼ N ( 1 , \frac{1}{2} ) ,$$

where T indicates transpose.

Using this strategy, the error can be computed with any loss function (e.g. mean-squared error or cross entropy) provided there is no temporal dependency, i.e. [symbol] [t] does not depend directly on variables in time step t−1. If such temporal dependencies exist, for example with Van Rossum spike distance, the complexity of the learning rule increases by a factor equal to the number of post-synaptic neurons. This increase in complexity would significantly complicate the design of the hardware. Consequently, an exemplary approach does not include temporal dependencies in the loss function.

The matrices J^{l} and H^{l} can be very large, especially in the case of convolutional networks. Because these matrices are not trained and are random, there is considerable flexibility in implementing them efficiently. One solution to the memory footprint of these matrices is to generate them on the fly, for example using a random number generator or a hash function. Another solution is to define J^{l} as a sparse, binary matrix. Using a binary matrix would further reduce the computations required to evaluate err.

The resulting learning dynamics imply no backpropagation through the main branch of the network. Instead, each layer learns individually. It is partly thanks to the local learning property that updates to the network can be made in a continual fashion, without artificial separation in learning and inference phases. An exemplary error-triggered learning algorithm in accordance with the present disclosure is provided below.

Algorithm 1 Error-triggered Learning Algorithm for layer l

```
Require: a minibatch of inputs and targets (Sⁱⁿ, Ŷ), previous
  weights W, previous θ, and previous learning rate η
Ensure: updated weights W, updated parameter θ.
  {1. Forward propagation:}
  Q = βQ + Sⁱⁿ
  P = αP + Q
  U ← WP − δR
  S ← Θ(U)
  {2. Gradient Computation:} [symbol]
    = Loss(S, Ŷ)
  $err ← \frac{\partial ℒ}{\partial U} = B ( U ) \frac{\partial ℒ}{\partial U}$
  for i = 1 do
    Eᵢ = − sign(errᵢ)(|errᵢ| ÷ θ)
    if Eᵢ^{l} ≠ 0 then [symbol]  Error triggered
      if B(Uᵢ) ≠ 0 then
        for j = 1 do
          if \tilde{P} ≥ \tilde{p} then
            Wᵢⱼ ← Wᵢⱼ + \tilde{η}Eᵢ
          end if
        end for
      end if
    end if
  θ ← Update(θ, E)
end for
```

An important feature of the error-triggered learning rule is its scalability to multi-layer networks with small and graceful loss of performance compared to standard deep learning. To demonstrate this experimentally, the learning dynamics are simulated for classification in large-scale, multi-layer spiking networks on a Graphical Processing Unit (GPU). The GPU simulations focus on event-based datasets acquired using a neuromorphic sensor, namely the N-MNIST and DVS Gestures dataset for demonstrating the learning model. Both datasets were pre-processed as in the work of J. Kaiser, H. Mostafa, and E. Neftci, “Synaptic plasticity for deep continuous local learning,” Frontiers in Neuroscience (April 2020). The N-MNIST network is fully connected (1000-1000-1000), while the DVS Gestures network is convolutional (64c7-128c7-128c7). In the simulations, all computations, parameters and states are computed and stored using full precision. However, according to the error-triggered learning rule, errors are quantized and encoded into a spike count. Note that in the case of box-shaped synaptic traces, and up to a global learning rate factor i, weight updates are ternary (−1,0,1) and can in principle, be stored efficiently using a fixed point format. For practical reasons, the neural networks were trained in minibatches of 72 (DVS Gestures) and 100 (N-MNIST). It is noted that the choice of using mini-batches is advantageous when using GPUs to simulate the dynamics and is not specific to Equation (4).

The error rate, denoted |E[t]|/1000, is the number of nonzero values for E[t] during one second of simulated time. The rate can be controlled using the parameter θ. While several policies can be explored for controlling θ and thus |E[t]|, present experiments used a proportional controller with set point Ē to adjust θ such as the error rate per simulated second during one batch, denoted [symbol] |E[t]| [symbol] , remains near Ē. After every batch, θ was adjusted as follows:

θ[t+1]=θ[t]+σ(E̅− [symbol] |E[t]| [symbol] ).

where σ is the controller constant and is set to 5×10⁻⁷ in the experiments. Thus, the proportional controller increases the value of θ when the error rate is too large, and vice versa.

The results shown in Table I (FIG. 3B) demonstrate a small loss in accuracy across the two tasks when updates are error-triggered using Ē=0.05, and a more significant loss when using Ē=0.01. Published works on DVS Gestures with spiking neurons trained with backpropagation achieved 5.41%, 6.36%, and 4.46% error rates and 1.3% for NMNIST with fully connected networks. It is emphasized here that the N-MNIST results are obtained using a multi-layer perceptron as opposed to a convolutional neural network. Spiking convolutional neural networks are capable of achieving lower errors on N-MNIST.

The results show final errors in the case of exact and approximate computations of

$$\frac{\partial U}{\partial W} .$$

Using the approximation \tilde{P} instead of

$$\frac{\partial U}{\partial W}$$

incurs an increase in error in all cases, due to the gradients becoming biased. Several approaches could be pursued to reduce this loss: (1) using stochastic computing and (2) multi-level discretization of

$$\frac{\partial U}{\partial W} .$$

A third conceivable option is to change the definition of P in the neural dynamics such that it is also thresholded, so as to match \tilde{P}. However, this approach yielded poor results because Pⱼ became insensitive to the inputs beyond the last spike.

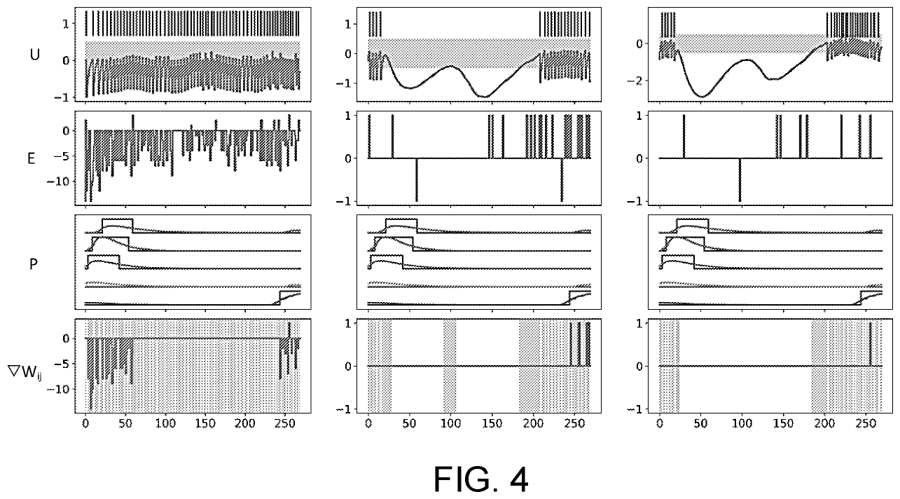

FIG. 4 illustrates the signals used to compute ΔWᵢⱼ^{l} in the case of one N-MNIST data sample, at the beginning (epoch=0), middle (epoch=2), and end of learning (epoch=15) for a fully connected network. There are many updates to the synaptic weights at the beginning of the learning, and several steps where |err|>1. However, the number of updates regress quickly after a few epochs. The initial surge of updates is due to (1) a large error in early learning and (2) a suboptimal choice of θ₀, the initial value of θ. The latter could be optimized for each dataset to mitigate the initial surge of updates.

At the top row of the figure, membrane potential U, of neuron i in layer 1, is overlaid with output spikes Sᵢ in the first layer. The shading shows the region where Bᵢ=1, e.g. the neuron is eligible for an update, and the fast, downwards excursions of the membrane potential are due to the reset (refractory) effect. The second row of the figure illustrates error events Eᵢ^{l} for neuron l, and the third row depicts post-synaptic potentials Pⱼ for five representative synapses. The box-shaped curves show \tilde{P} terms used to compute synaptic weight gradients ∇_{w}_{ᵢⱼ} for the shown synapses. The bottom row of the figure shows resulting weight gradients for the shown synapses. The shading show regions where Bᵢ=1. In these regions, if an error was present (Eᵢ≠0), and \tilde{P}>0, then an update was made. Intuitively, learning corresponds to “masking” the values E according to the neuron and synapse states.

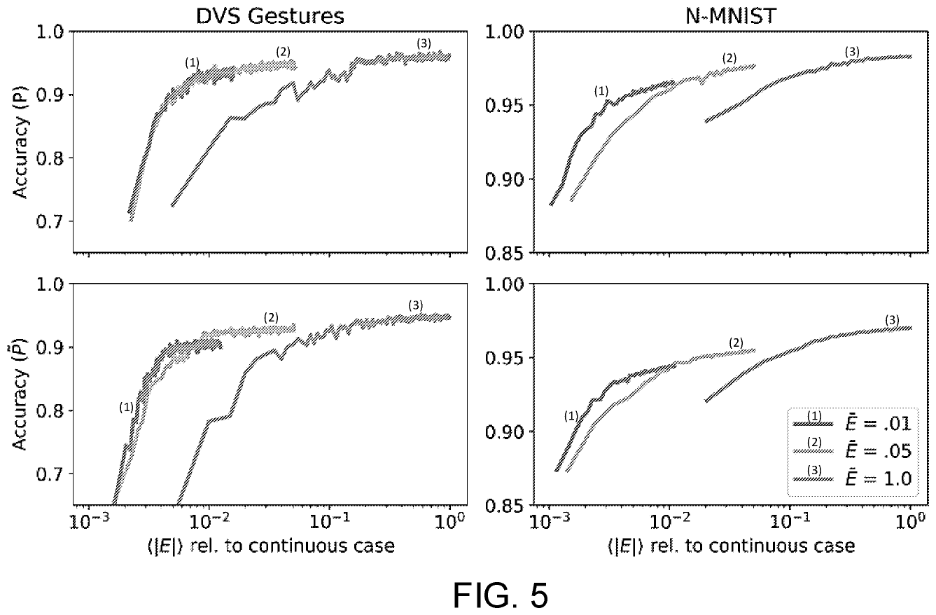

It is conceivable that the role of event-triggered learning is merely to slow down learning compared to the continuous case. To demonstrate that this is not the case, task accuracy is shown versus the number of updates [symbol] |E| [symbol] relative to the continuously learning case in FIG. 5. In particular, the first row shows the results using the exact postsynaptic potential (PSP), i.e. P, and the second row shows the results when using the approximate PSP \tilde{P}, respectively. For each experiment, three different target error rates Ē were selected. The horizontal axis show the total number of updates relative to the non-error-triggered case (Ē=1). In all cases, Ē=0.05 provided nearly an order of magnitude fewer updates for a small cost in accuracy.

These curves indicate that values of Ē<1 indeed reduce the number of parameters updates to reach a given accuracy on the task compared to the continuous case. Even the case Ē=005 leads to a drastic reduction in the number of updates with a reasonably small loss in accuracy. However, a too low error event rate, here Ē=0.01 can result in poorer learning compared to Ē=0.05 along both axes (e.g. FIG. 5, bottom right, Ē=0.01). This is especially the case when the approximate traces \tilde{P} are used during learning and implies the existence of an optimal tradeoff for Ē that maximizes accuracy versus the error rate.

It is noted that the weight updates can be achieved through stochastic gradient descent (SGD). SGD is used here because other optimizers with adaptive learning rates with momentum involve further computations and states that would incur an additional overhead in a hardware implementation. To take advantage of the GPU parallelization, batch sizes were set to 72 (DVS Gestures) and 200 (N-MNIST). Although, batch sizes larger than 1 are not possible locally on a physical substrate, training with batch size 1 is just as effective as using batches. The inventors' earlier work demonstrated that training with batch size 1 in SNNs is indeed effective, but cannot take advantage of GPU accelerations.

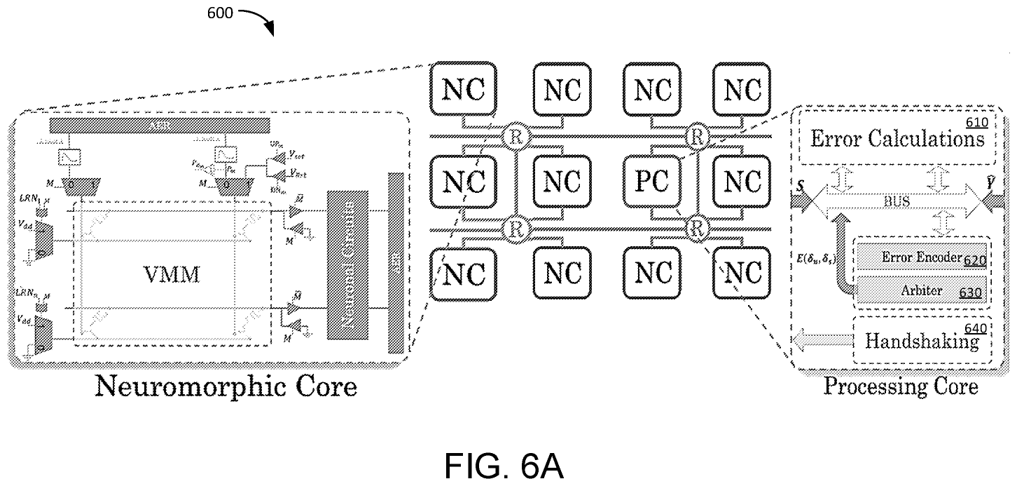

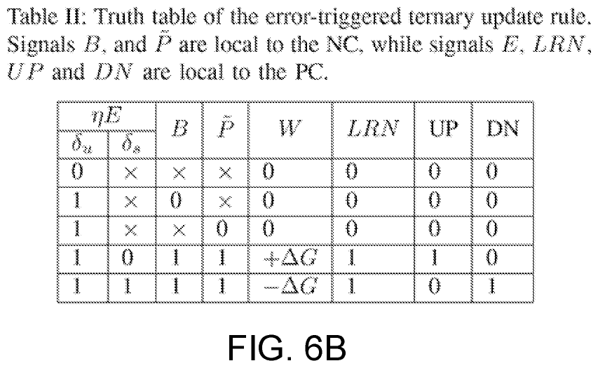

Error-triggered learning (Equation (6)) requires signals that are both local and non-local to the SNN. The ternary nature of the rule enables a natural distribution of the computations across core boundaries, while significantly reducing the communication overhead. An exemplary hardware architecture 600 contains Neuromorphic Cores (NCs) and Processing Cores (PCs) as depicted in FIG. 6A. The NCs are responsible for implementing the neuron and synapse dynamics described in Equation (1). Each core additionally contains circuits that are needed for implementing training. In various embodiments, the error signals are calculated on the PCs and communicated asynchronously to the NCs. Thus, each core can function independently without affecting each other.

In addition to data and control buses, the PC contains four main blocks, namely for error calculation 610, error encoding 620, arbitration 630, and handshaking 640. The PC can be shared among several NCs, where communication across the two types of cores is mediated using the same address event routing conventions as the NCs.

The error calculation block 610 is responsible for calculating the gradients and the continuous-value of the error updates (i.e., err^{l} signals). The PC also compares the error signal err with the threshold θ as discussed in Equations (5) and (6) to generate integer E signals that are sent to error encoder 620. A natural approach to implement this block is by using a Central Processing Unit (CPU) in addition to a shared memory which is similar to the Lakemont processors on the Intel Loihi research processor. CPUs offer high speed, high flexibility, and programming ability that is generally desirable when calculating loss functions and their gradients. The shared memory can be used to store the spike events while calculating a different layer error. The calculated error update signals E are rate-encoded in the error encoder into two spike trains E→{δᵤ,δₛ}, where δᵤ is the update signal and δₛ is the polarity of the update.

The arbiter 630 is used to choose only one NC to update at time. This choice can be based on different policies, for instance, least frequently updated or equal policy. Once the {δᵤ,δₛ} signals are generated, they need to be communicated to the corresponding NC. For this communication, a handshaking block 640 is required. The generated error events send a request to the PC arbiter 630, which acknowledges one of them (usually based on the arrival times). The address of the acknowledged event along with a request is communicated to the NC core in a packet. The handshaking block 640 at the NC ensures that the row whose address matches the packet receives the event and takes control over the array. This block then sends back an acknowledge to the PC as soon as the learning is over. The communication bus is then freed up and is made available for the next events.

An alternative to implementing the PC is to use another NC, as it is a SNN that can be naturally configured to implement the necessary blocks for communication and error encoding. Functions can be computed in SNNs, for example, by using the neural engineering framework. In this case, the system could include solely of NCs. The homogeneity afforded by this alternative may prove desirable for specific technologies and designs.

Emerging technologies, such as Resistive RAM (RRAMs), Phase Change Memories (PCMs), Spin Transfer Torque RAMs (STT-RAMs), and other MOS realizations such as floating gate transistors, assembled as an RCA enable the VMM operation to be completed in a single step. This is unlike general-purpose processors that require N×M steps where N and M are the weight matrix's size. These emerging technologies implement only positive weight (excitatory connections). However, to fully represent the neural computations, negative weights (inhibitory connections) are also necessary. There are two ways to realize the positive and negative weights: (1) balanced realization where two devices are needed to implement the weight value stored in the devices conductances where W=G⁺−G₋. If the G⁺ is greater/less than G₋, it represents positive/negative weight, respectively; and (2) unbalanced realization where one device is used to implement the weight value with a common reference conductance G_{ref}, set to the mid-value of the conductance range. Thus, the weight value can be represented as W=G−G_{ref}. If the G is greater/less than G_{ref}, it represents a positive/negative weight, respectively. In various embodiments, an unbalanced realization is used, since it saves area and power at the expense of using half of the device's dynamic range. Thus, the memristive SNN can be written as:

$${U}_{i}^{l} [ t ] = {\sum }_{j} ( {G}_{ij}^{l} - {G}_{ref} ) {P}_{j}^{l} [ t ] - δ {R}_{i} [ t ] . \qquad ( 7 )$$

NCs implement the presynaptic potential circuits that simulate the temporal dynamics of P in Equation (1). In addition, the NC implements the memristor write circuitry which potentiate or depress the memristor with a sequence of pulses depending on the error signal that is calculated in the PC. The NC continuously works in the inference mode until it enters the learning mode by receiving an error event from the PC. The circuit then deactivates all rows except the row where the error event belongs to. The memristors within this row are then updated by a positive or negative pulse based on the \tilde{P} value, which would potentiate or depress the device by ±ΔG as shown in Table II (FIG. 6B). Thus, the control signals can be written as follows:

$${UP}_{j} = \overline{{δ}_{s}} {\tilde{P}}_{j} {DN}_{j} = {δ}_{s} {\tilde{P}}_{j}$$

$${lrn}_{i} = {B}_{i} {δ}_{u} LRN = {\sum }_{i} {lrn}_{i}$$

where LRN is the mode signal which determine the mode of the operation—either inference (LRN=0) or weight update mode (LRN=1). The update mode is chosen if any of the lrn signals is turned ON. It is worth mentioning that local learning was considered where each layer learns individually. As a result, there is no backpropagation as known in the conventional sense. The loss gradient calculations are performed in the processing core with floating point precision to calculate the error signals. These are then quantized and serially encoded into ternary pulse stream to program the memristors.

The neuromorphic and processing cores are linked together with a Network on Chip (NoC) that organizes the communication among them based on the widely used Address Event Representation (AER) scheme. Different routing techniques can be used to tradeoff between flexibility (i.e., degree of configurability) and expandability. For instance, TrueNorth and Loihi chips use 2D mesh NoC, SpiNNiker uses torus NoC, and HiAER uses tree NoC. HiAER offers high flexibility and expandability, which can be used in an exemplary architecture for communication among neuromorphic cores during inference and between the processing core and neuromorphic cores during training.

A full update cycle of the NC is Tᵤ_{ₘₐₓ}=N×fₑᵣ_{ₘₐₓ}×Tₚ where N is the fan-out per NC, fₑᵣ_{ₘₐₓ} is the maximum error frequency, and Tₚ is the width of the memristor update period. Tᵤ_{ₘₐₓ} should be much smaller than the inter-spike interval (i.e. factor of 10 will be sufficient). Assuming that the maximum firing rate of the neuron is fₙ_{ₘₐₓ}, a condition on maximum error frequency can be derived as

$${f}_{{er}_{max}} < \frac{1}{10 N {f}_{{n}_{max}} {T}_{p}}$$

This shows a tradeoff between the fan-out per NC and the maximum error frequency. If we consider Tₚ=100 ns and fₙ_{ₘₐₓ}=100 Hz, the maximum error frequency under this definition is 78 Hz for N=128 (a typical size of the current fabricated RCA) and 10 Hz for N=103. As previously evaluated, the higher the error frequency, the better the performance. The hardware would set the upper limit for the error frequency to 10 Hz for N=103, which causes 2.68% and 4.22% drop in the performance. Depending on the distribution of the spike trains from the error calculation block, this constraint can be further loosened. While a buffer can also be added to the PC to queue the error events which are blocked as a result of the busy communication bus, this translates to more memory and hence area on the PC and lead to biased gradients.

A similar analysis can be done to calculate the maximum input dimension of the array. Assuming there is no structure in the incoming input (or that the structure is not available a priori), a Poisson statistic can be considered for the input spikes. In that case, the probability of the next spike in any of the M inputs occurring within the pulse width of the write pulse Tₚ is equal to P(Event)=1−e^{-Mf}^{ᵢₙ}^{T}^{ₚ} where fᵢₙ is the frequency of the input spikes. To keep this probability low (e.g., <0:01), the fan-in can be calculated. Considering a biologically plausible maximum rate of fᵢₙ=100 Hz, in the worst case where all input neurons fire and for Tₚ=100 ns, the maximum M would be 1000. The SNN test benches, such as DVSGesture and N-MINST, have peak event rates around 30 Hz and 15 Hz respectively which would triple the fan-in of the NC.

Assuming that the PC runs at frequency f_{clk}, and it takes 2N/f_{clk} on average to calculate the error signals (which can be 2/f_{clk} in the case of a RCA or 2N²/f_{clk} in case of a von-Neumann architecture). The factor 2 is added for J and H multiplications in addition to loss calculation evaluation time Tₗ. Thus, the total error calculation per NC takes T_{pc}=2N/f_{clk}+Tₗ. Updates have to be performed faster than the time constant for computing the gradient. Thus, the maximum number of NCs is N=T_{pc}/Tᵤ_{ₘₐₓ}. For example, for f_{clk}=500 MHz and N=1000 and Tᵤ_{ₘₐₓ}=1 ms, 4000 NCs can be used per RCA-based PC on average and 4 NCs for von-Neumann-based PC. It is noted that handshaking, arbiter, and the error encoder are operating in parallel with the error calculations and thus we did not include them in the estimation.

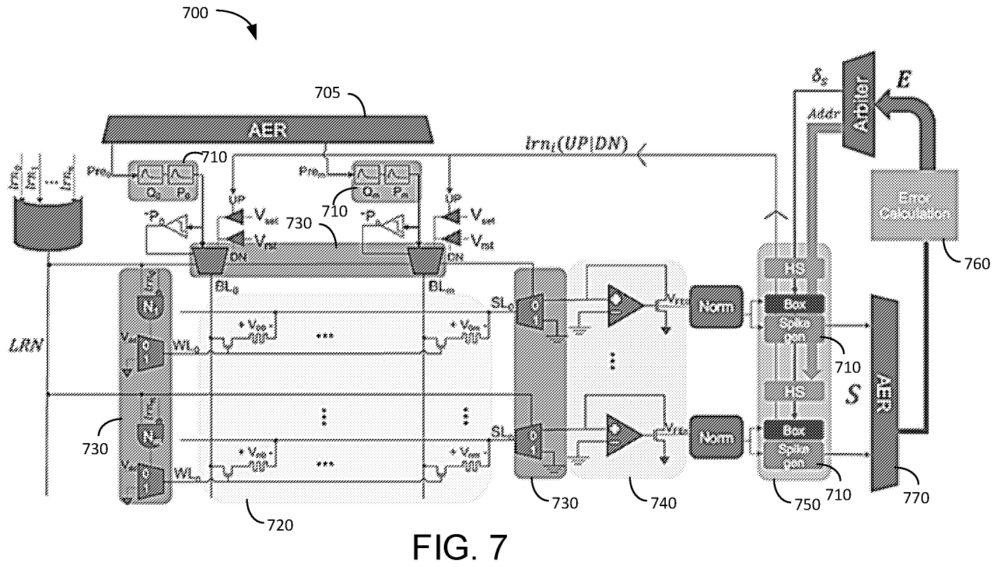

Next, the neuromorphic learning architecture compatible with a 1T-1R RCA and the signal flow from the input events to the learning core are introduced. An exemplary SNN circuit implementation differs from classical ones used in mixed-signal neuromorphic chips. Generally, the rows of crossbar arrays are driven by spikes and integration takes place at each column. While this is beneficial in reducing read power, it renders learning more difficult because the variables necessary for learning in SNNs are not local to the crossbar. Instead, various embodiments use the crossbar as a VMM of presynaptic trace vectors P^{l} and synaptic weight matrices W^{l}. Using this strategy, the same trace Pᵢ^{l} per neuron supports both inference and learning. This property has the distinctive advantage for learning in that it is immune to the mismatch in Pᵢ^{l}, and can even exploit this variation. AER is the conventional scheme for communication between neuronal cores in many neuromorphic chips. FIG. 7 depicts a neuromorphic learning architecture 700 as a crossbar compatible with the AER communication scheme. Event integrators are denoted with label 710, VMM array is denoted with label 720, switches are denoted with label 730, front end is denoted with label 740, neural circuits are denoted with label 750, and error calculation block is denoted with label 760.

The information flows from the AER 705 at the input columns to the integrators 710, then to the VMM 720, and finally to the spike generator (spike gen) block which sends the output spikes to the row AER 770. Through the row AER 770, information flows to the PC to calculate the error, which in turn sends error events back to the VMM 720 to change the synaptic weights.

The 1T-1R array of memristive devices is driven by the appropriate voltages on the WL, SL, BL for inference and learning. During inference, the voltages across the memristor are proportional to the respective P value. The current from the RCA gets normalized in the Norm block which is fed to the box and spike gen blocks in block 750. The spikes S from the spike gen are given to the error calculation block which sends the arbitrated error events with the address of the learning row to the handshaking blocks (HS). This communication gives the control of the array to the learning row which sends back the lrnᵢ signals to the RCA.

Pre-synaptic events communicated via AER are integrated in the Q blocks, which are then integrated in P blocks, as shown in FIG. 7. This doubly integrated signal drives the RCA during inference mode. The RCA model used here is a 1 T-1R array of memristive devices with the gate and source of the transistor being driven by the WL and BL respectively and the bottom electrode of the device being driven by the SL. The voltages driving the WL, BL and SL are muxed at the periphery to drive the array with the appropriate voltages depending on the inference or learning mode. It is worth noting that in exemplary simulations, we did not use a specific model for the devices. Any type of device whose conductance can be changed with a voltage pulse can be used in this type of architecture. Specifically, the exemplary architecture matches well with Oxide-based Resistive RAM (OxRAM) and Conductive Bridge RAM (CBRAM) type of devices.

In inference mode, WL is set to V_{dd} which turns on the selector transistor, BL is driven by buffered P voltages, and the SL is connected to a Transimpedance Amplifier (TIA) which pins each row of the array to a virtual ground. The current from the RCA is dependent on the value of the memristive devices. To ensure subthreshold operation for the next state of the computation, a normalizer block is used. The normalized output is fed both to a spike generator (spike gen) and a learning block (box). The pulse generator block acts as a neuron that only performs a thresholding and resetting function since its integration is carried out at the P block. The generated S spikes are communicated to the error generator block through the AER scheme as well as other layers. The learning block generates the box function described in Equation (4).

In the learning mode, the array will be driven by the appropriate programming voltages on WL, BL, and SL to update the conductance of the memristive devices. Since the whole array will be affected by the BL and SL voltages, at any point in time only one row of devices can be programmed. Since in an exemplary approach, the updates will be done on the error events which are generated per neuron, this architecture maps naturally to the error-triggered algorithm as the error events are generated for each neuron and hence per row. The error events are generated through the error calculation block 760 shown in FIG. 7. This block can be implemented by another SNN or any nonlinear function of spike S implemented by a digital core. The calculated errors are encoded in UP and DN learning events for every neuron of the array. Since only one neurons' synapses can be updated at any point in time, these learning signals are arbitrated and the access to the learning bus will be granted to the learning signals of one neuron. The address of the acknowledged neuron is sent to the Handshaking blocks (HS) at each row (through Addr bus shown in FIG. 7) along with the sign of the update (δₛ). The corresponding row i whose address matches Addr receives the address and its box block generates the lrnᵢ signal depending on the B value as specified in Table II (FIG. 6B). The WL, remains at V_{dd} and all the other WLⱼ, j≠i switch to zero such that neuron i takes control over the array (implemented by gates N, in FIG. 7 which perform the AND operation between [symbol] , and LRN signals which is the output of the OR operation between all lrnᵢ signals). Once in the learning mode indicated by the OR output (LRN signal), SL is switched to a common mode voltage (virtual ground) which blocks learning signals to the neurons. The voltage on BL, (hence the Vᵢⱼ in the figure) depends on the state of is \tilde{P}ⱼ which is a binary value as a result of comparing Pⱼ with a threshold as is shown in FIG. 7. In accordance with the truth Table II (FIG. 6B), on the arrival of the UP or DN event, if Bᵢ and \tilde{P}ⱼ are non-zero, voltage Vₛₑₜ or Vᵣₛₜ will get applied to BLᵢ respectively. Once learning is over, the handshaking block elicits an acknowledge signal to the error calculating block which frees up the array and the Addr and δₛ wait for the next request.

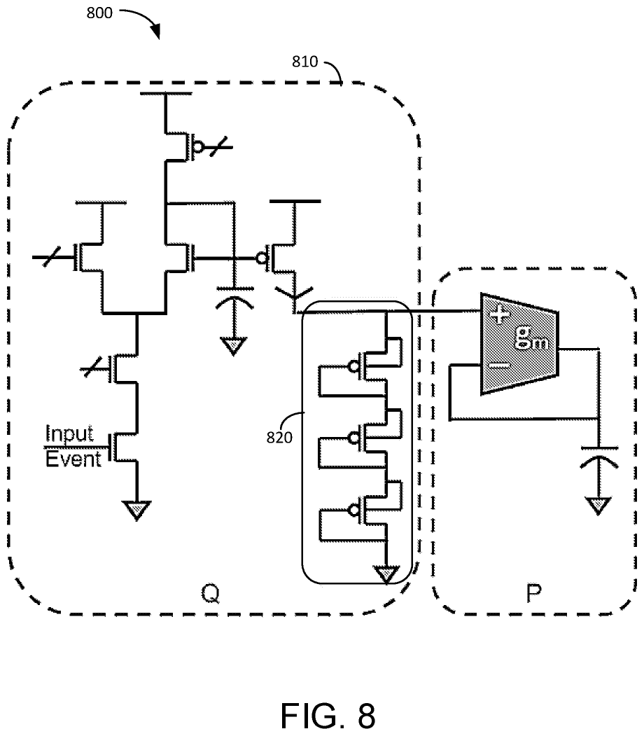

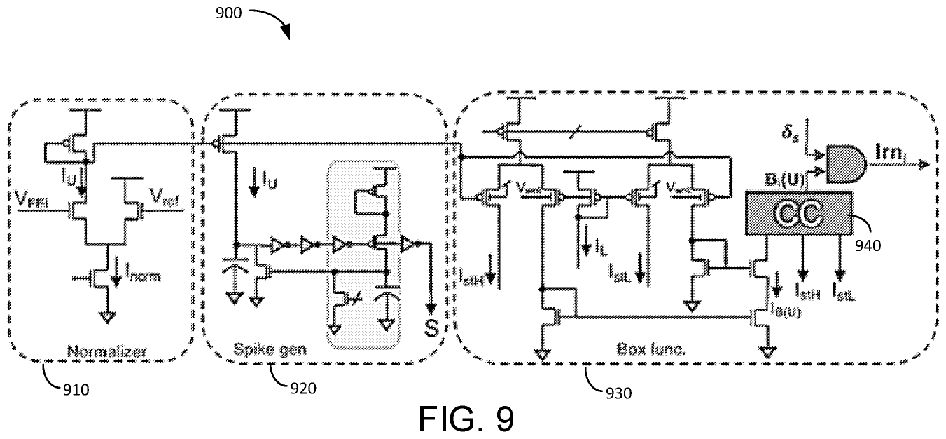

Next, FIG. 8 shows circuitry 800 for a double integration scheme using Q and P integrators in accordance with various embodiments of the present disclosure. As is explained in FIG. 6A, Q integrator is a DPI circuit (denoted with label 810) whose output current is converted to a voltage by the pseudo resistor (denoted with label 820). P integrator is a GₘC filter. At the arrival of the Pre, events from the AER input, the trace Qⱼ is generated through the DPI circuit 810 in FIG. 8 which generates a tunable exponential response in the form of a sub-threshold current. The sub-threshold current is linearly converted to voltage using pseudo resistors in the pseudo resistor block 820 in FIG. 8. The first-order integrated voltage is fed to a GₘC filter giving rise to a second-order integrated output Pⱼ which is buffered to drive the entire crossbar column in accordance with Equation (1). Output voltage Pⱼ is applied to the top electrode of the corresponding memristive device (Wⱼᵢ) whose bottom electrode is pinned by the crossbar front-end TIA. This block pins the entire row to virtual ground (in the present case common mode voltage is set as half V_{dd}) and reads out the sum of the currents generated by the application of Pₛ across the memristors in the row. As a result, voltage V_{FEi} is developed on the gate of the transistor at the output of the TIA which feeds to a normalizer circuit shown in FIG. 9.

Accordingly, FIG. 9 illustrates exemplary learning circuitry 900 representing normalizing, spike generation, and box functions in accordance with various embodiments of the present disclosure. The normalizer circuit 910 normalizes the current from the crossbar array to Iₙₒᵣₘ set by the tail of the differential pair. Spike generator circuit 920 is a simple current to frequency (C2F) converter generating spike S of the neurons. The highlighted part depicts the circuit implementing the refractory period to limit the firing rate and hence power consumption of the block. The box function 930 gates the learning signals UP and DN by its output B(U). It is implemented with a bump circuit where the bump current I_{B(U)} gets compared to the anti-bump currents by current comparator (CC) and when higher, B(U) has a binary value of 1 allowing learning to happen.

In various embodiments, the normalizer circuit 910 is a differential pair which re-normalizes the sum of the currents from the crossbar to Iₙₒᵣₘ, ensuring that the currents remain in the sub-threshold regime for the next stage of the computation which is (i) the box function B(U) as is specified in Equation (5) implemented by the box block 930 and (ii) the spike generation block 920 which gives rise to S.

The box function B(U) can be carried out by a modified version of the Bump circuit which is a comparator and a current correlator (CC) that detects the similarity and dissimilarity between two currents in an analog fashion, as shown in box 940 of FIG. 9. The width of the transfer characteristics of the Bump current directly implements the box function B(U) where Iᵤ is close to I_{L} (condition u₋<Uᵢ^{l}<u₊). Unlike the original Bump circuit, Variable Width Bump (VWBump) enables configurability over the width of the box function by changing the well potential V well. Moreover, the tunability of I L allows setting the offset of the box function with respect to the normalized crossbar current. The details of using this circuit for learning is explained in the works of M. Payvand and G. Indiveri, “Spike-Based Plasticity Circuits for Always-On On-Line Learning in Neuromorphic Systems,” in 2019 IEEE International Symposium on Circuits and Systems (ISCAS) (2019), pp. 1-5. The output of VWBump circuit gates the arbitrated UP and DN signals from the PC to indicate the sign of the weight update (up or down) or stop-learning (no update).

The spike generation block 920 can be carried out via a simple current to frequency (C2F) circuit, which directly translates Iᵤ to spike frequency S. The highlighted part implements the refractory period, which limits the spiking rate of this block.

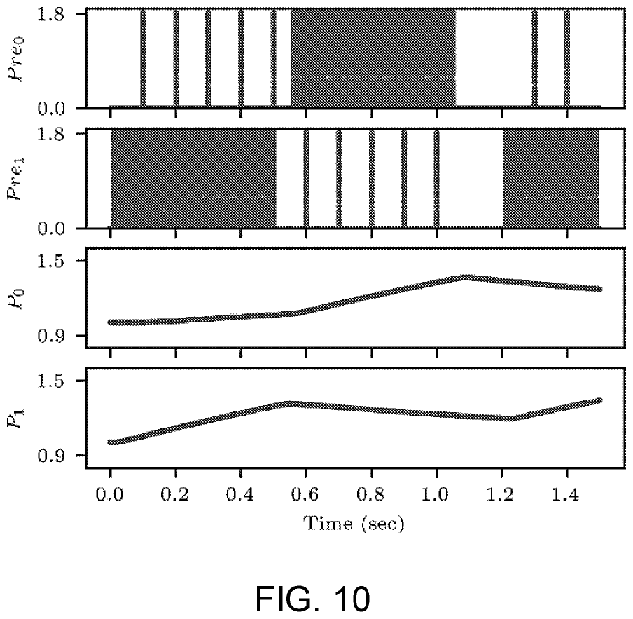

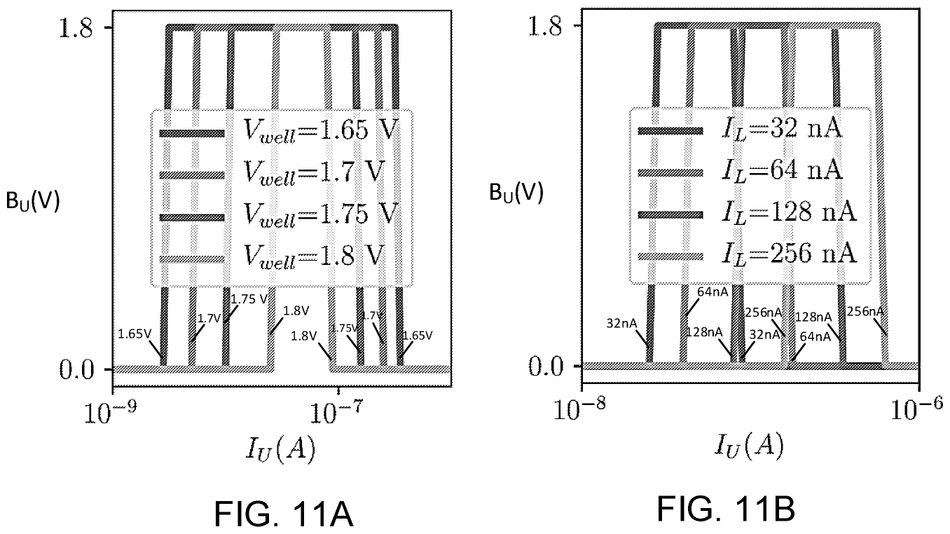

For the present disclosure, simulations results, showing the characteristics and output of the learning blocks, were conducted for a standard CMOS 180 nm process. FIG. 10 shows the output of the double integration of the input events Pre, coming from the AER. Pre₀ and Pre₁ and subsequently P₀ and P₁ are plotted as examples. Pᵢ smoothly follows the instantaneous firing rate of Preᵢ as is expected. Correspondingly, FIGS. 11A-11B shows the characteristics of the box function 930 and its configurability using the circuit parameters. In FIG. 11A, the width of the box is tuned by the well potential shown in FIG. 9, and in FIG. 11B, bias parameter I_{L} controls the offset of the box function 930 with respect to the normalized sum of the currents from the crossbar array.

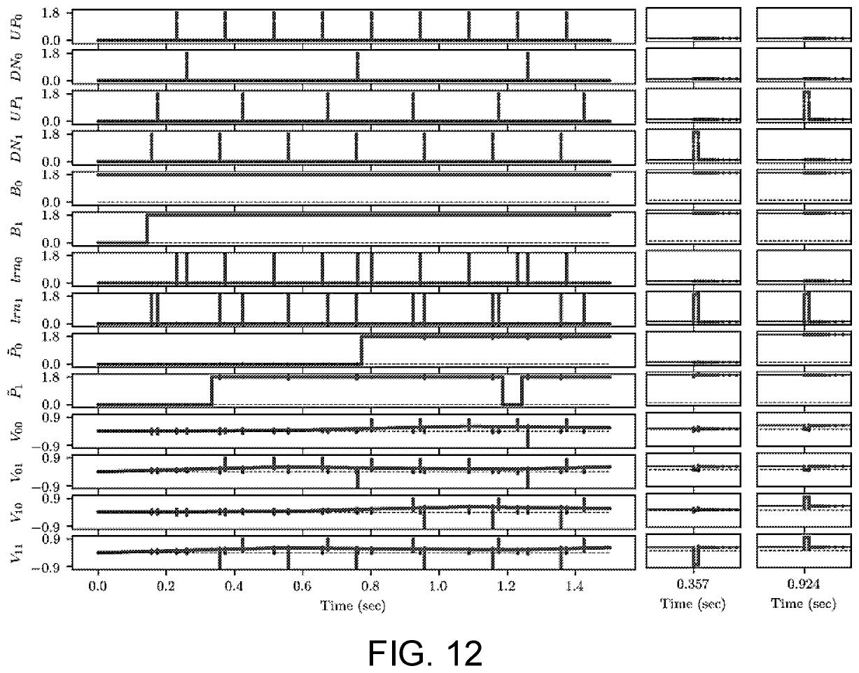

FIG. 12 illustrates various plots of learning signals along with the voltages that are dropped across the memristive devices for a 2×2 array in different scenarios. As shown in the figure, there are two δₛ signals (UPᵢ and DNᵢ) with their respective box output (Bᵢ) and the output of the learn gate feeding back to the array (lrnᵢ), and the binary thresholded value of the input signal Pⱼ shown as \tilde{P}ⱼ. The voltage across the devices matches Table II (FIG. 6B). On the onset of lrnᵢ signal, if Bᵢ and Pᵢ are non-zero, Vₛₑₜ or Vᵣₛₜ is applied across the device Wⱼᵢ (in this case 0.9V and −0.9V respectively), otherwise the voltage across the device is zero. To better illustrate the voltage across the devices, two-time windows are zoomed in and plotted around 0.357 s and 0.924 s. In the two cases, the lrn₁ signal is activated which should only update the devices in the second row. Thus, the voltages V₀₀ and V₀₁ turn to zero while the lrn₁ signal is high. In the case of the 0.357 s time window, DN₁ is high and P₀ and P₁ are low and high respectively. Therefore, the voltage across V₁₀ is also zero while V₁₁ is equal to Vᵣₛₜ to decrease the conductance as a result of the DN signal. In the case of the 0.924 s time window, UP₁ is high and P₀ and P₁ are both high. Therefore, the voltages V₁₀ and V₁₁ are both equal to Vₛₑₜ to increase the conductance as a result of the UP signal.

In accordance with the present disclosure, an exemplary hardware architecture supports an always-on learning engine for both inference and learning. By default, the Resistive Crossbar Array (RCA) operates in the inference mode where the devices are read based on the value of P voltages. On the arrival of error events, the array briefly enters a learning mode, during which it is blocked for inference. During the learning mode, input events are missed. The length of the learning mode depends on the pulse width required for programming the memristive devices, which could be less than 10 ns up to 100 ns depending on their type. Therefore, based on the frequency of the input events, the maximum size of the array can be calculated. The 1T-1R memory can be banked with this maximum size.

From testing of exemplary neuronal circuits, the average power and area of the neuronal circuits including the normalizer and box function is estimated to be about 100 nW and 1000 μm² respectively. For the spike generator block 920, the power of the block depends on the time constant of the refractory period which bounds the frequency of the C2F block. If the time constant is set to 10 ms to limit the frequency to 100 Hz, the average power consumption of the block is about 10 uW. The area of the block is about 400 μm². For exemplary filters and RCA drivers, the average power and area of these presynaptic circuits including \tilde{P} generation are estimated around 2 mW and 3000 μm², respectively. The area and power of the buffer is estimated for the case where it can support up to 1 mA of current. This current is dictated by the size of the array.

By proceeding from first principles, namely surrogate gradient descent, the present disclosure presents an exemplary design for general-purpose, online SNN learning machines. The factorization of the learning algorithm as a product of three factors naturally delineates the memory boundaries for distributing the computations. In the present disclosure, this delineation is realized through NCs and PCs. The separation of the architecture in NCs and PCs is consistent with the idea that that neural networks are generally stereotypical across tasks, but loss functions are strongly task-dependent. The only non-local signal required for learning in an NC is the error signal E, regardless of which task is learned. The ternary nature of the three-factor learning rule and the sparseness afforded by the error-triggering enable frugal communication across the learning data path.

This architecture is not as general as a Graphical Processing Unit (GPU), however, for the following reasons: (1) the RCA inherently implements a fully connected network and (2) due to reasons deeply rooted in the spatiotemporal credit assignment problem, loss functions must be defined for each layer, and these functions may not depend on past inputs. The first limitation (1) can be overcome by elaborating on the design of the NC, for example by mapping convolutional kernels on arrays. There exists no exact and easy solution to the second limitation. However, recent work, such as random backpropagation and local learning, can be used to address this limitation in some embodiments. Finally, although only feedforward weights were trained in the simulations, the approach is fully compatible with recurrent weights as well.

Since learning is error-triggered, every event can only have one sign and hence for every update, the devices on a row i corresponding to non-zero \tilde{P}ⱼs are updated either to higher or lower conductances together and not both at the same time. This allows sharing the MUXes at the periphery of the array, making the architecture scalable, since the size of the peripheral circuits grow linearly, while the size of the synapses grows quadratically with the number of neurons.

For peripheral circuits, the size of the P buffer and TIA at the end of the row is dependent on the amount of its driving current I_{drive} which is a function of the fan-out N. Specifically, in the worst case where all the devices are in their low resistive state, the driving current of the buffer should support:

I_{drive}=N*V_{read}/LRS

where LRS is the low resistive state and V_{read} is the read voltage of the memristive devices. Assuming V_{read} of 200 mV which is a typical value for reading ReRAM and a low resistance of 1 kΩ, in the worst case when all the devices are in their low resistive state, to drive an array with fan-out of 100 neurons, the buffer needs to be able to provide 2 mA of current. This constraint can be loosened by having a statistic of the weight values in a neural network. For more sparse connectivity this current will drop significantly.

Regarding the impact of Error-triggered Learning on hardware, the error-update signals are reduced from 8e6 to 96.7e3 and from 1.3e6 to 14.7e3 for DVSGesture and NMINST, respectively, after applying the error-triggered learning with a small impact of the performance. This reduction is directly reflected on improving the total write energy and lifetime of the memristors with 82:7× and 88:4× for DVSGesture and NMINST, respectively which are considered bottleneck for online learning with memristors. A variant of the error-triggered learning has been demonstrated on the Intel Loihi research chip, which enabled data-efficient learning of new gestures where learning one new gesture with a DVS camera required only 482 mJ. Although the Intel Loihi does not employ memristor crossbar arrays, the benefits of error-triggered learning stem from algorithmic properties, and thus extend to the crossbar array.

In brief, the present disclosure derived a local and ternary error-triggered learning dynamics compatible with crossbar arrays and the temporal dynamics of SNNs. The derivation reveals that circuits used for inference and training dynamics can be shared, which simplifies the circuit and suppresses the effects of fabrication mismatch. By updating weights asynchronously (when errors occur), the number of weight writes can be drastically reduced. An exemplary learning rule has the same computational footprint as error-modulated STDP but is functionally different in that there is no acausal part, the updates are triggered on errors if the membrane potential is close to the firing threshold (rather than post-synaptic spike STDP). A more detailed comparison of the scaling of this family of learning rules is provided in the work of Kaiser, et al. In addition, an exemplary hardware and algorithm can be integrated into spiking sensors such as a neuromorphic Dynamic Vision Sensor to enable energy-efficient computing on the edge thanks to the learning algorithm of various embodiments of the present disclosure.

Despite the huge benefit of the crossbar array structure, memristor devices suffer from many challenges that might affect their performance unless taken into consideration in training, such as asymmetric non-linearity, precision, and retention. Solutions studied to address these non-idealities, such as training in the loop or adjusting the write pulse properties to compensate them, are compatible with the learning approach presented in the present disclosure. Fortunately, on-chip learning helps with other problems such as sneak path (i.e. wire resistance), variability, and endurance. Various embodiments of the present disclosure combine these solutions and an exemplary learning approach. Interestingly, with error-triggered learning, only selected devices are updated and have a direct positive impact on endurance by reducing the number of write events. The reduction of write events is directly proportional to the set error rate [symbol] |E| [symbol] , and can be adjusted based on the device characteristics. This leads to extending the lifetime of the devices and less write energy consumption.

It should be emphasized that the above-described embodiments are merely possible examples of implementations, merely set forth for a clear understanding of the principles of the present disclosure. Many variations and modifications may be made to the above-described embodiment(s) without departing substantially from the principles of the present disclosure. All such modifications and variations are intended to be included herein within the scope of this disclosure.

Therefore, at least the following is claimed:

1. A neural network learning system comprising:
an input circuitry module;
a multi-layer spiked neural network with memristive neuromorphic hardware;
a weight update circuitry module, and
wherein the input circuitry module is configured to receive an input current signal and convert the input current signal to an input voltage pulse signal utilized by the memristive neuromorphic hardware of the multi-layered spiked neural network module and is configured to transmit the input voltage pulse signal to the memristive neuromorphic hardware of the multi-layered spiked neural network module;
wherein the multi-layer spiked neural network is configured to perform a layer-by-layer calculation and conversion on the input voltage pulse signal to complete an on-chip learning to obtain an output signal;
wherein the multi-layer spiked neural network is configured to transmit the output signal to the weight update circuitry module;
wherein the weight update circuitry module is configured to implement a synaptic function by using a conductance modulation characteristic of the memristive neuromorphic hardware and is configured to calculate an error signal and based on a magnitude of the error signal, trigger an adjustment of a conductance value of the memristive neuromorphic hardware so as to update synaptic weight values stored by the memristive neuromorphic hardware.

2. The system of claim 1, wherein the memristive neuromorphic hardware comprises memristive crossbar arrays.

3. The system of claim 2, wherein a row of a memristive crossbar array comprises a plurality of memristive devices.

4. The system of claim 3, wherein the error signal is generated for each row of the memristive crossbar array, wherein for an individual error signal, each of the plurality of memristive devices of a row associated with the individual error signal is updated together based on a magnitude of the individual error signal.

5. The system of claim 1, wherein the input circuitry module comprises pseudo resistors.

6. The system of claim 1, wherein the weight update circuitry module is configured to generate a signal to update the synaptic weight values or to bypass updating the synaptic weight values based on the magnitude of the error signal.

7. The system of claim 6, wherein the weight update circuitry module increases the synaptic weight values.

8. The system of claim 6, wherein the weight update circuitry module decreases the synaptic weight values.

9. The system of claim 1, wherein updating of synaptic weights are triggered based on a comparison of the magnitude of the error signal within an error threshold value.

10. The system of claim 9, wherein the error threshold value is adjustable by the weight update circuitry module.

11. A method comprising:
receiving an input current signal;
converting the input current signal to an input voltage pulse signal utilized by a memristive neuromorphic hardware of a multi-layered spiked neural network module;
transmitting the input voltage pulse signal to the memristive neuromorphic hardware of the multi-layered spiked neural network module;
performing a layer-by-layer calculation and conversion on the input voltage pulse signal to complete an on-chip learning to obtain an output signal;
sending the output signal to a weight update circuitry module; and
calculating, by the weight update circuitry module, an error signal and based on a magnitude of the error signal, triggering an adjustment of a conductance value of the memristive neuromorphic hardware so as to update synaptic weight values stored by the memristive neuromorphic hardware.

12. The method of claim 11, wherein: the memristive neuromorphic hardware comprises memristive crossbar arrays, a row of a memristive crossbar array comprises a plurality of memristive devices, the error signal is generated for each row of the memristive crossbar array, and for an individual error signal, each of the plurality of memristive devices of a row associated with the individual error signal is updated together based on a magnitude of the individual error signal.

13. The method of claim 11, further comprising generating, by the weight update circuitry module, a signal to update the synaptic weight values or to bypass updating the synaptic weight values based on the magnitude of the error signal.

14. The method of claim 11, wherein updating of synaptic weights are triggered based on a comparison of the magnitude of the error signal within an error threshold value.

15. The method of claim 14, wherein the error threshold value is adjustable by the weight update circuitry module.
